(19) United States
(12) Patent Application Publication
(10) Pub. No.: US 2025/0275382 A1
(43) Pub. Date: Aug. 28, 2025

(54) LIGHT EMITTING DISPLAY DEVICE

(71) Applicant: LG Display Co., Ltd., Seoul (KR)

(72) Inventors: Hee Su BYEON, Paju-si (KR); Sae Mi PARK, Paju-si (KR)

(73) Assignee: LG Display Co., Ltd., Seoul (KR)

(21) Appl. No.: 18/984,279

(22) Filed: Dec. 17, 2024

(30) Foreign Application Priority Data
Feb. 27, 2024 (KR) 10-2024-0028397

(51) Int. Cl. H10K 59/124; H10K 59/80

(52) U.S. Cl. CPC H10K 59/124; H10K 59/80518

(57) ABSTRACT

A light emitting display device can includes a substrate having a driving circuit in each of sub-pixels, an insulating layer provided on the driving circuit, a reflective electrode disposed in the insulating layer and connected to the driving circuit, a trench provided in the insulating layer while neighboring the reflective electrode, and a light emitting element including an anode. The anode can overlap with the reflective electrode and contact the reflective electrode in an interior of the trench.

### CROSS-REFERENCE TO RELATED APPLICATIONS

This application claims priority to Korean Patent Application No. 10-2024-0028397, filed in the Republic of Korea on Feb. 27, 2024, the entire contents of which is hereby expressly incorporated by reference into the present application.

### BACKGROUND

### Field

The present disclosure relates to a light emitting display device, and more particularly to a light emitting display device capable of achieving an enhancement in aperture ratio while preventing generation of lateral leakage current.

### Discussion of the Related Art

A display device displays an image to a user. For this function, the display device can include light emitting elements.

Each of the light emitting elements can be connected to a lower circuit including a transistor provided on a substrate, for driving thereof.

Recent display devices are used for various applications. As one example of such applications, a method in which a display device is disposed adjacent to the eyes of the user has been proposed. In this case, pixels should be disposed in a small area corresponding to the eye and, as such, high resolution is needed. For clear display, high luminance is also needed. To this end, research on the development of a display device having the high resolution and high luminance is being conducted.

### SUMMARY OF THE DISCLOSURE

Accordingly, the present disclosure is directed to a light emitting display device that substantially obviates one or more problems due to limitations and disadvantages of the related art.

An object of the present disclosure is to provide a light emitting display device capable of preventing generation of lateral leakage current between adjacent sub-pixels in a high resolution structure in which light emitting elements are driven by a low current.

Another object of the present disclosure is to provide a light emitting display device having an enhanced aperture ratio through change of a connection structure to a driving circuit.

Another object of the present disclosure is to provide a light emitting display device capable of achieving low-grayscale expression of a sub-pixel without being influenced by driving of another sub-pixel adjacent to the former sub-pixel.

Another object of the present disclosure is to provide a light emitting display device capable of achieving process optimization.

Another object of the present disclosure is to provide a light emitting display device having effects of reduced power consumption, high efficiency, and high luminance, thereby having sustainability.

To achieve these objects and other advantages and in accordance with the purpose of the disclosure, as embodied and broadly described herein, a light emitting display device includes a substrate including a driving circuit in each of sub-pixels, an insulating layer provided on the driving circuit, a reflective electrode disposed in the insulating layer and connected to the driving circuit, a trench provided in the insulating layer while neighboring the reflective electrode, and a light emitting element including an anode overlapping with the reflective electrode and contacting the reflective electrode in an interior of the trench.

### BRIEF DESCRIPTION OF THE DRAWINGS

The accompanying drawings, which are included to provide a further understanding of the disclosure and are incorporated in and constitute a part of this application, illustrate embodiment(s) of the disclosure and along with the description serve to explain the principle of the disclosure. In the drawings:

FIG. 1 is a diagram schematically showing a light emitting display device according to an embodiment of the present disclosure;

FIG. 2 is a circuit diagram showing a circuit of a sub-pixel of FIG. 1 in accordance with an embodiment;

FIG. 3 is a plan view showing a light emitting display device according to a first embodiment of the present disclosure;

FIG. 4 is a cross-sectional view taken along line I-I′ in FIG. 3 according to the first embodiment;

FIG. 5 is a cross-sectional view taken along line II-II′ in FIG. 3;

FIGS. 6A to 6C are cross-sectional views showing various examples of trenches according to an embodiment of the present disclosure;

FIGS. 7A and 7B are sectional views showing different forms of a light emitting element according to an embodiment of the present disclosure, respectively;

FIG. 8 is a cross-sectional view taken along line I-I′ in FIG. 3 in accordance with a second embodiment of the present disclosure;

FIG. 9 is a cross-sectional view taken along line II-II′ in FIG. 3 in accordance with the second embodiment of the present disclosure;

FIG. 10 is a cross-sectional view taken along line I-I′ in FIG. 3 in accordance with a third embodiment of the present disclosure; and

FIG. 11 is a cross-sectional view taken along line II-II′ in FIG. 3 in accordance with the third embodiment of the present disclosure.

### DETAILED DESCRIPTION OF THE EMBODIMENTS

Reference will now be made in detail to preferred embodiments of the disclosure, examples of which are illustrated in the accompanying drawings. Wherever possible, the same reference numbers will be used throughout the drawings to refer to the same or like parts. In the following description of the disclosure, detailed descriptions of known functions and configurations incorporated herein will be omitted when the same can obscure the subject matter of the disclosure. In addition, the names of elements used in the following description are selected in consideration of clarity of description of the disclosure, and can differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings.

In the present disclosure, where terms such as “including,” “having,” “comprising,” and the like are used, one or more components can be added, unless the term, such as “only,” is used. As used herein, the term “and/of” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the disclosure, a “first” component can be the same as a “second” component within the technical concept of the present disclosure, unless specifically mentioned otherwise. Further, the term “can” fully encompasses all the meanings and coverages of the term “may.”

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

In the disclosure, a stack means a unit structure including a hole transport layer, a common layer including an electron transport layer, and an emission layer disposed between the hole transport layer and the electron transport layer. In the common layer, a hole injection layer, an electron blocking layer, a hole blocking layer, an electron injection layer, etc. can be further included. In addition, other organic layers or inorganic layers can be further included in the stack in accordance with a structure or design of a light emitting element.

A light emitting display device according to various embodiments of the present disclosure will now be discussed referring to the drawings. All the components of each light emitting display device according to all embodiments of the present disclosure are operatively coupled and configured.

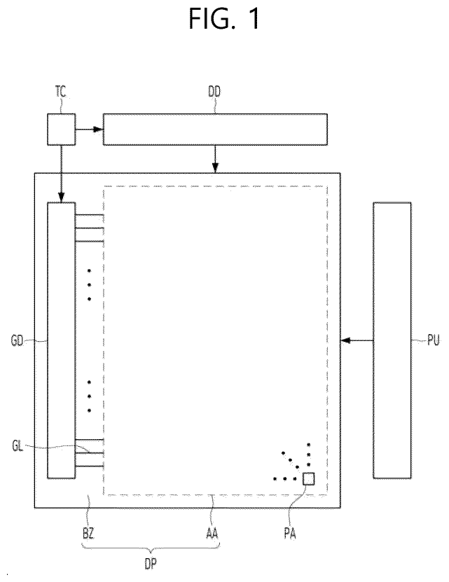

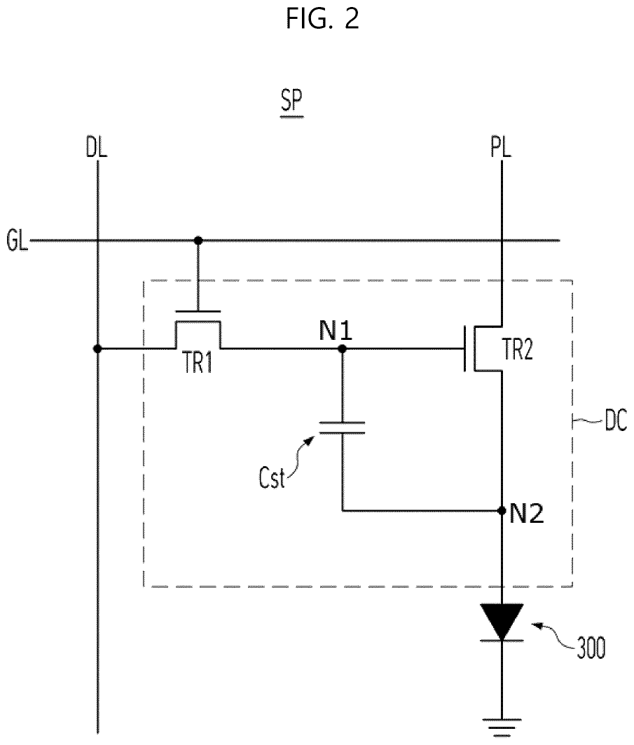

FIG. 1 is a diagram schematically showing a light emitting display device according to an embodiment of the present disclosure. FIG. 2 is a circuit diagram showing a circuit of a sub-pixel of FIG. 1 in accordance with an embodiment of the present disclosure.

As shown in FIGS. 1 and 2, the light emitting display device according to the embodiment of the present disclosure can include a display panel DP. The display panel DP can generate an image to be provided to the user. For example, a plurality of pixel areas PA can be disposed in the display panel DP. Each pixel area PA can render various colors. For example, each pixel area PA can include a plurality of sub-pixels SP. Various signals can be applied to each sub-pixel SP through signal lines GL, DL, and PL. For example, the signal lines GL, DL, and PL can include gate lines GL each configured to apply a gate signal, data lines DL each configured to apply a data signal, and a power voltage supply lines PL each configured to supply a power supply voltage.

The gate lines GL can be electrically connected to a gate driver GD. The data lines DL can be electrically connected to a data driver DD. The gate driver GD and the data driver DD can be controlled by a timing controller TC. For example, the gate driver GD can receive clock signals, reset signals, and a start signal from the timing controller TC, and the data driver DD can receive digital video data and a source timing signal from the timing controller TC. The power voltage supply lines PL can be electrically connected to a power unit PU.

The display panel DP can include an active area AA (or display area) in which the pixel areas PA are disposed, and a bezel area BZ disposed outside the active area AA. The bezel area BZ can be disposed outside the pixel areas PA. For example, the active area AA can be surrounded by the bezel area BZ. The gate driver GD, the data driver DD, the timing controller TC, and the power unit PU can be disposed outside the active area AA. For example, respective signal lines GL, DL, and PL can include areas disposed on the bezel area BZ. At least one of the gate driver GD, the data driver DD, the timing controller TC, and the power unit PU can be disposed on the bezel area BZ of the display panel DP. For example, the light emitting display device according to the embodiment of the present disclosure can be a gate-in-panel (GIP) type light emitting display device in which the gate driver GD is directly formed on a substrate in the bezel area BZ. In this case, a GIP can include a plurality of transistors and a plurality of capacitors, and the transistors and capacitors included in the GIP can be manufactured using the same process as that of transistors disposed on the substrate in the active area AA.

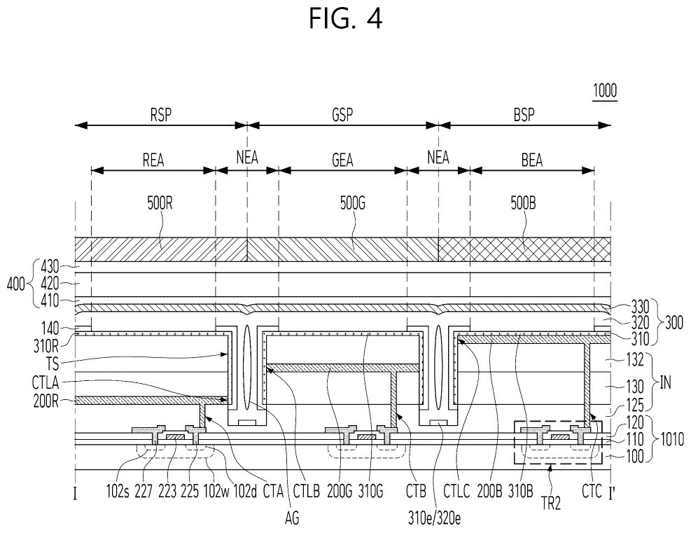

As shown in FIG. 2, each sub-pixel SP can emit light representing a particular color in accordance with signals applied thereto through signal lines GL, DL, and PL. For example, a driving circuit DC, which is electrically connected to a light emitting element (cf. “300” in FIG. 4), can be disposed in each sub-pixel SP. The display panel DP can include a substrate (cf. “100” in FIG. 4) configured to support the driving circuit DC of each sub-pixel SP and the light emitting element 300.

The operation of the light emitting element 300 disposed in each sub-pixel SP can be controlled by signals applied to the light emitting element 300 through the signal lines GL, DL, and PL.

For example, the driving circuit DC of each sub-pixel SP can include a first transistor TR1, a second transistor TR2, and a storage capacitor Cst.

A first source/drain electrode (for example, a drain electrode) of the first transistor TR1 is electrically connected to the data line DL, and a second source/drain electrode (for example, a source electrode) of the first transistor TR1 is electrically connected to a gate electrode of the second transistor TR2. Here, a connection node between the first transistor TR1 and the second transistor TR2 is referred to as a first node N1.

The first transistor TR1 transmits, to the first node N1, a data signal supplied through the data line DL in response to a scan signal supplied through the gate line GL.

The storage capacitor Cst is electrically connected between the first node N1 and a second node N2, and, as such, charges a voltage applied to the first node N1 therein.

A first source/drain electrode (for example, a drain electrode) of the second transistor TR2 receives a high-level drive voltage EVDD through the power voltage supply line PL, and a second source/drain electrode (for example, a source electrode) is electrically connected to an anode of the light emitting element 300. The second transistor TR2 can control an amount of a drive current flowing through the light emitting element 300, corresponding to a voltage applied to the gate electrode thereof.

The first transistor TR1 of each sub-pixel SP can transmit, to the second transistor TR2 of the same sub-pixel SP, a data signal supplied to the data line DL in accordance with a gate signal applied to the gate line GL. For example, the first transistor TR1 of each sub-pixel SP can function as a switching transistor, and the second transistor TR2 of each sub-pixel SP can function as a driving transistor.

For example, the driving circuit DC of each sub-pixel SP can supply, to the light emitting element 300 of the same sub-pixel SP, a drive current corresponding to a data signal in accordance with a gate signal. The drive current supplied by the drive circuit DC of each sub-pixel SP can be maintained for one frame by the storage capacitor Cst of the same sub-pixel SP.

Hereinafter, a detailed configuration of the light emitting display device according to embodiments of the present disclosure will be described with reference to the accompanying drawings.

### First Embodiment

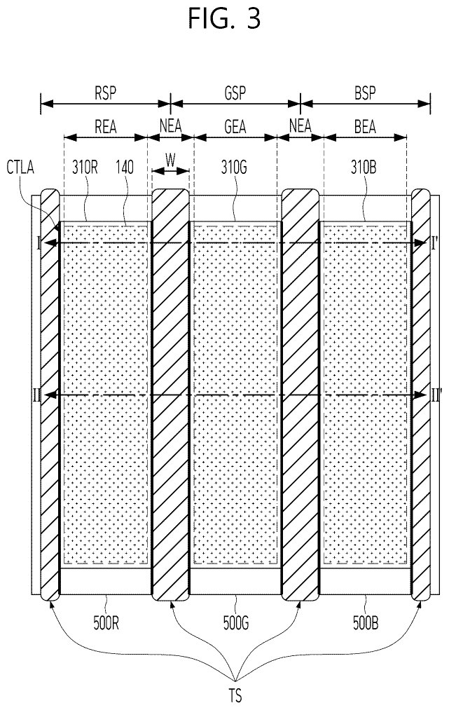

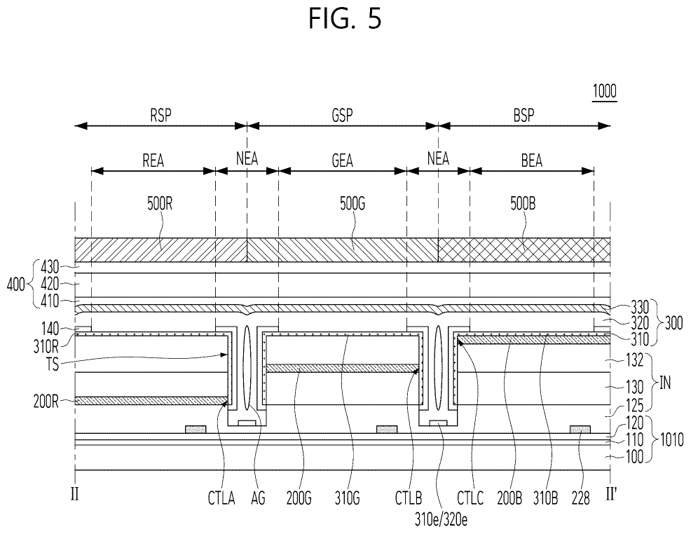

FIG. 3 is a plan view showing a light emitting display device according to a first embodiment of the present disclosure. FIG. 4 is a cross-sectional view taken along line I-I′ in FIG. 3. FIG. 5 is a cross-sectional view taken along line II-II′ in FIG. 3.

As shown in FIGS. 3 to 5, the light emitting display device according to the first embodiment of the present disclosure, which is designated by reference numeral “1000”, includes a substrate 100 including driving circuits (cf. “DC” in FIG. 2) (DC: TR1, TR2, and Cst) disposed at respective sub-pixels RSP, GSP, and BSP, an insulating layer IN provided on the driving circuits DC (TR1, TR2, and Cst), and reflective electrodes 200R, 200G, and 200B disposed in the insulating layer IN while being connected to the driving circuits DC, respectively.

In addition, the light emitting display device 100 according to the embodiment of the present disclosure can further include trenches TS provided in the insulating layer IN while neighboring corresponding ones of the reflective electrodes 200R, 200G, and 200B, and anodes 310 (310R, 310G, and 310B) overlapping with the reflective electrodes 200R, 200G, and 200B while contacting the reflective electrodes 200R, 200G, and 200B in the trenches TS, or at an interior of the trenches TS, respectively.

A red sub-pixel RSP, a blue sub-pixel BSP, and a green sub-pixel GSP can be disposed adjacent to one another on the substrate 100.

In respective sub-pixels RSP, GSP, and BSP, emission areas REA, BEA, and GEA can be defined in areas corresponding to the anodes 310 (310R, 310B, and 310G), respectively, and areas among the emission areas REA, BEA, and GEA can be defined as non-emission areas NEA, respectively. When fences 140 are provided at edges of the anodes 310 (310R, 310G, and 310R), areas including areas of the fences 140 and the trenches TS can be non-emission areas.

The driving circuit DC provided at each of the sub-pixels RSP, GSP, and BSP includes a first transistor TR1 having a switching function, a second transistor TR2 configured to supply a drive current to the light emitting element 300, and a storage capacitor Cst configured to be concerned with a capacity between gate and source electrodes of the second transistor TR2 in order to maintain the drive current for one frame. Among the constituent elements of the driving circuit DC, the second transistor TR2 is connected to a corresponding one of the anodes 310 (310R, 310B, and 310G) of the light emitting element 300.

Active layers of at least the first and second transistors TR1 and TR2 of the driving circuit DC can utilize the substrate 100.

The substrate 100 can include silicon, and can be defined with a well region through doping thereof with an impurity and, as such, the substrate 100 itself can directly function as active layers of the transistors. Accordingly, in the light emitting display device according to the embodiment of the present disclosure, a wafer including silicon can be used as the substrate 100, and the well region of the substrate 100 can be used as an active layer of a transistor, and, as such, it can be possible to omit a process of forming a separate active layer. Accordingly, there are advantages in terms of integration and process simplification suitable for realization of fine sub-pixels.

FIG. 4 shows a part of areas of the sub-pixels of FIG. 3 in which respective second transistors TR2 are formed.

Referring to FIG. 4, connection of the second transistors TR2 and the reflective electrodes 200R, 200G, and 200B is shown.

Adjacent ones of the sub-pixels RSP, GSP, and BSP are divided from each other by respective trenches TS. Areas of respective sub-pixels RSP, GSP, and BSP divided by the trenches TS can be used as the emission areas REA, GEA, and BEA on the whole or can be used as the emission areas REA, GEA, and BEA, except for areas overlapping with the fences 140 covering the edges of the anodes 310R, 310G, and 310B.

In the light emitting display device 100 according to the embodiment of the present disclosure, the anodes 310R, 310G, and 310B can be provided at the entirety of the sub-pixels RSP, GSP, and BSP on the insulating layer IN and, as such, the entire area of the anodes 310R, 310G, and 310B can be used as an emission area.

In addition, as shown in FIG. 4, in the light emitting display device 1000 according to the first embodiment of the present disclosure, the anodes 310R, 310G, and 310B are not directly connected to respective second transistors TR2 disposed thereunder, but are connected to respective second transistors TR2 through connection holes CTA, CTB, and CTC, respectively. In addition, the reflective electrodes 200R, 200G, and 200B extend between side walls of adjacent ones of the trenches TS and, as such, connection between the reflective electrodes 200R, 200G, and 200B and the anodes 310R, 310G, and 310B can be achieved through the trenches TS having a great depth, in place of connection holes.

Here, when the trenches TS have a structure having a small width W and a great depth, in a process of depositing a material of the anodes 310R, 310G, and 310B, each of the anodes 310R, 310G, and 310B may not be formed to extend to lower surfaces of the corresponding trench TS disposed at a deep depth or can be divided between the side wall and the lower surface of the trench TS. In this case, the anodes 310R, 310G, and 310B on the side walls of the trenches TS can be separated from anode materials 310e on the lower surfaces of the trenches TS, respectively. Accordingly, when the depth of the trenches TS is great, as shown in FIGS. 4 and 5, separation of the anodes 310 (310R, 310G, and 310B) based on the sub-pixels RSP, GSP, and BSP can be achieved in accordance with the shape of the trenches TS in the deposition process without using a separate patterning process.

In this case, each trench TS has a great depth, as compared to the width W thereof. For example, the width W of the trench TS can be 1 μm or less, preferably, 0.5 μm or less, and more preferably, 0.1 μm or less. In addition, the depth of the trench TS can be greater than the thickness of the insulating layer IN in which at least the reflective electrodes 200R, 200G, and 200B are formed. The thickness of the insulating layer IN can exceed 1 μm, and can reach several tens of μm. Accordingly, the reflective electrodes 200R, 200G, and 200B are disposed in the insulting layer IN at the sub-pixels RSP, GSP, and BSP while having different vertical phases, respectively, and the trenches TS can have lower surfaces disposed below the reflective electrode 200R having a deepest vertical phase in the insulating layer IN.

The light emitting display device according to the embodiment of the present disclosure can achieve structural separation on a sub-pixel basis by the trenches TS. Each trench TS has a greater depth in a normal direction of the substrate 100 than a length thereof in a horizontal direction of an X-Y plane which is a formation surface of the substrate 100. In this case, separation of the anodes 310R, 310G, and 310B on a sub-pixel basis can be possible by the trenches TS, and connection between the side walls of the trenches TS and the reflective electrodes 200R, 200G, and 200B can be possible in an anode formation process.

Accordingly, in the light emitting display device according to the embodiment of the present disclosure, it can be possible to omit a process such as a connection hole formation process for connection of the anodes 310R, 310G, and 310B to respective second transistors disposed thereunder. In accordance with omission of the connection holes to be connected to the anodes, it can be possible to prevent degradation of an aperture ratio and degradation of luminous efficacy occurring due to design of the reflective electrodes to bypass contact hole areas.

Effects of the embodiment of the present disclosure will be described in comparison with a structure in which an anode is directly connected to a transistor without formation of a trench.

For example, in a light emitting display device having a structure in which an anode is directly connected to a transistor without formation of a trench, a reflective electrode should be removed from a connection area between the anode and the transistor, for connection between the anode and the transistor. In this case, it is impossible to obtain a micro-cavity effect between the reflective electrode and a cathode in the area from which the reflective electrode is removed and, as such, luminous efficacy can be degraded. In addition, an area protruding from the reflective electrode, for connection thereof to the transistor, can be difficult to be used as an effective emission area in a sub-pixel associated therewith. Furthermore, generation of greenhouse gases inevitably occurs due to an etchant or the like consumed in processes of forming a contact hole and patterning the anode, for connection between the anode and the transistor. Meanwhile, in a light emitting display device configured to divide sub-pixels by fences covering edges of anodes without formation of trenches, it is impossible to prevent generation of lateral current leakage caused by an intermediate layer, using only the fences which have a thin structure.

The light emitting display device according to the embodiment of the present disclosure can solve or address the above-described problems/limitations in that the light emitting display device includes a trench, and connection between an anode and a reflective electrode is achieved at a side wall of the trench. In particular, when the anode and the reflective electrode have the same potential in accordance with connection therebetween, a parasitic voltage generated at a dielectric material between the anode and the reflective electrode can be removed. In addition, when the anode and the reflective electrode have the same potential in accordance with connection therebetween, potential variation of the anode having variation characteristics can be prevented by virtue of electrical interference between the reflective electrode and the anode occurring in a reflective electrode structure disposed in the form of an island.

In addition, the trenches TS can enable separation of the intermediate layer 320 of the light emitting element 300 on a sub-pixel basis. The intermediate layer 320 includes a hole injection layer, a hole transport layer, an emission layer, an electron transport layer, and an electron injection layer, and can be manufactured using a common mask for a plurality of sub-pixels. In a deposition process, at least a portion of the intermediate layer 320 is separated from areas around the trenches TS through structural separation holes such as the trenches TS and, as such, separation of the intermediate layer 320 on a sub-pixel basis is possible. In FIGS. 4 and 5, an air gap AG in each trench TS is shown. At least a part of a plurality of layers constituting the intermediate layer 320 is separated between adjacent ones of the sub-pixels RSP, GSP, and BSP at opposite sides of the air gap AG and, as such, an intermediate layer byproduct 320e separated from the intermediate layer 320 can remain on an anode material 310e at the lower surface of the trench TS. As a result, a horizontal continuous structure of the intermediate layer 320 is disconnected among the sub-pixels and, as such, independent driving on a sub-pixel basis is possible, and generation of lateral leakage current can be prevented.

As shown in FIGS. 4 and 5, the reflective electrodes 200R, 200G, and 200B at respective sub-pixels RSP, GSP, and BSP can be disposed while occupying the entire area of the sub-pixels RSP, GSP, and BSP among the trenches TS, and can be disposed to contact side walls of adjacent ones of the trenches TS.

At respective sub-pixels RSP, GSP, and BSP, the reflective electrodes 200R, 200G, and 200B are disposed to overlap with the anodes 310R, 310G, and 310B, respectively, when viewed in plan view, and the reflective electrodes 200R, 200G, and 200B and the anodes 310R, 310G, and 310B have, at side walls of the trenches TS, side contacts CTLA, CTLB, and CTLC each contacting the trenches TS disposed at opposite sides thereof or the trench TS disposed at one side thereof, respectively.

In the light emitting display device according to the embodiment of the present disclosure, each trench TS can have a lower surface disposed at a level deeper than the reflective electrodes 200R, 200G, and 200B. The sub-pixels RSP, GSP, and BSP are required to have resonance distances according to different resonance conditions based on colors of light emitted from the sub-pixels RSP, GSP, and BSP, respectively. Although the light emitting elements 300 provided at respective sub-pixels RSP, GSP, and BSP can have the same structure including the anode 310 (310R, 310G, and 310B), the intermediate layer 320, and the cathode 330, it can be possible to adjust resonance distances respectively corresponding to red, green, and blue of emitted light by adjusting vertical phases of the reflective electrodes 200R, 200G, and 200B disposed under the anode 310 to be different from one another.

In the case of FIGS. 4 and 5, for example, the first reflective electrode 200 R is disposed in the red sub-pixels RSP at a position having a lowest vertical phase, the third reflective electrode 200B is disposed in the blue sub-pixel BSP at a position having a highest vertical phase, and the second reflective electrode 200G is disposed in the green sub-pixel GSP at a position between the vertical phases of the first and third reflective electrodes 200R and 200B.

The insulating layer IN includes, for example, a first insulating layer 125 configured to protect the second transistors TR2, a second insulating layer 130 configured to cover the first reflective electrode 200R provided on the first insulating layer 125, and a third insulating layer 132 configured to protect the second reflective electrode 200G provided on the second insulating layer 130.

In this case, the third reflective electrode 200B in the blue sub-pixel BSP can contact a lower surface of the third anode 310B.

The reflective electrodes 200R, 200G, and 200B of respective sub-pixels RSP, GSP, and BSP can include a material having high reflectance. For example, the reflective electrodes 200 of respective sub-pixels RSP, GSP, and BSP can include a reflective metal such as aluminum (Al) or silver (Ag) or an alloy thereof. In the display device according to the embodiment of the present disclosure, in addition to a facing electrode structure constituted by the anodes 310 (310R, 310G, and 310B) and the cathode 330, the separate reflective electrodes 200R, 200G, and 200B are added to respective emission areas REA, GEA, and BEA, and the vertical phases of the reflective electrodes 200R, 200G, and 200B are disposed at positions where optimum micro-cavity effects according to respective wavelengths in the sub-pixels RSP, GSP, and BSP are generated. Accordingly, an enhancement in light extraction efficiency can be achieved.

In respective sub-pixels RSP, GSP, and BSP, light reflected by the cathode 330 in the light emitting element 300 can be again reflected by the reflective electrodes 200R, 200G, and 200B.

Distances between respective reflective electrodes 200 and respective anodes 310 in respective emission areas REA, BEA, and GEA of respective sub-pixels SP can be different from one another in accordance with colors rendered by respective emission areas REA, BEA, and GEA. For example, the distance between the first reflective electrode 200R and the first anode 310R in the red emission area REA can be greater than the distance between the second reflective electrode 200G and the second anode 310G in the green emission area GEA. The distance between the second reflective electrode 200G and the second anode 310G in the green emission area GEA can be greater than the distance between the third reflective electrode 200B and the third anode 310B in the blue emission area BEA. For example, in the blue emission area BEA, the third reflective electrode 200B can directly contact the third anode 310B. In the light emitting display device according to the embodiment of the present disclosure, accordingly, the wavelength range of light emitted from each of the emission area REA, BEA, and GEA can be determined by a micro-cavity structure.

The red sub-pixel RSP corresponds to a longest wavelength one of red, green, and blue and, as such, can have a longest vertical resonance distance between the first reflective electrode 200R and the cathode 330, and the blue sub-pixel BSP corresponds to a shortest wavelength one of red, green, and blue and, as such, can have a shortest vertical resonance distance between the third reflective electrode 200B and the cathode 330.

The light emitting element 300 includes a red emission layer, a green emission layer, and a blue emission layer at emission layers provided at the intermediate layer 320 and, as such, can represent white light through a combination of colors of light emitted from the emission layers.

The light emitting element 300 has the same shape in the red sub-pixel RSP, the green sub-pixel GSP, and the blue sub-pixel BSP and, as such, the red sub-pixel RSP, the green sub-pixel GSP, and the blue sub-pixel BSP include the first to third reflective electrodes 200R, 200G, and 200B having different vertical phases, respectively, in order to reinforce micro-cavity effects corresponding to respective wavelength colors.

In this case, the red sub-pixel RSP is set such that the vertical distance between the first reflective electrode 200R and the cathode 330 is proportional to a red wavelength, the green sub-pixel GSP is set such that the vertical distance between the second reflective electrode 200G and the cathode 330 is proportional to a green wavelength, and the blue sub-pixel BSP is set such that the vertical distance between the third reflective electrode 200B and the cathode 330 is proportional to a blue wavelength. Accordingly, micro-cavity effects corresponding to respective colors of emitted light can be obtained and, as such, color reproducibility can be enhanced in respective sub-pixels without provision of color filters 500R, 500G, and 500B.

In addition, when the third reflective electrode 200B and the third anode 310B contact each other in the blue sub-pixel BSP, the vertical distance between the third reflective electrode 200B and the cathode 330 is proportional to the blue wavelength and, as such, the light emitting element 300 can have a resonance condition corresponding to blue.

The light emitting display device 1000 according each embodiment of the present disclosure is a near-eye display device configured to be used in a state of being adjacent to the eyes of a viewer. For example, the sub-pixels are densely disposed in the limited area of the substrate 100. In the near-eye display device, the configuration of a light emitting display device including a substrate is disposed near the eyes of the viewer in the form of eyeglasses or a head-up display device and, as such, can express virtual reality (VR) or augmented reality (AR). Accordingly, in the near-eye display device, the size of the substrate should be as small as a few inches, and a plurality of sub-pixels should be densely disposed between the eyes of the viewer, as compared to the configuration of a display device configured to be used at a certain distance from the eyes of a viewer, as in a portable phone, a television, or the like. Accordingly, a plurality of sub-pixels should be densely disposed in the limited area of the substrate, for image display, and, as such, the size of each sub-pixel is very small. Accordingly, in the small-size sub-pixels, respective anodes thereof should have a small size, and low-current driving should be carried out. Even in low-current driving, the sub-pixels should also achieve high-luminance expression.

Referring to FIG. 4, in the light emitting display device according to the embodiment of the present disclosure, widths of the emission areas REA, BEA, and GEA of respective sub-pixels are several m or less and widths of the trenches TS among adjacent ones of the sub-pixels are 1 μm or less, and as such, the size of each sub-pixel is very small. Accordingly, light emission can be possible using even a small drive current.

In the light emitting display device according to the embodiment of the present disclosure, connection between the light emitting element 300 and respective driving circuits can be achieved through respective reflective electrodes 200R, 200G, and 200B extending to corresponding side walls of the trenches TS. The contact of respective reflective electrodes may contact the driving circuit in an emission area of the sub-pixel corresponding thereto.

In respective sub-pixels RSP, GSP, and BSP, the first reflective electrode 200R can be connected to the second transistor TR2 corresponding thereto through a contact hole CTA provided at the first insulating layer 125, the second reflective electrode 200G can be connected to the second transistor TR2 corresponding thereto through a contact hole CTB provided at the first insulating layer 125, and the third reflective electrode 200B can be connected to the second transistor TR2 corresponding thereto through a contact hole CTC provided at the first insulating layer 125.

The first to third reflective electrodes 200R, 200G, and 200B repeat reflection in an upward direction when light generated from the light emitting element 300 is incident thereupon after being emitted and, as such, resonance effects can be obtained. Areas of the first to third reflective electrodes 200R, 200G, and 200B extend to be adjacent to side walls of the trenches TS corresponding thereto and, as such, the entirety of the formation surfaces of the first to third reflective electrodes 200R, 200G, and 200B can be used for resonance effects.

In the light emitting display device according to the embodiment of the present disclosure, the substrate 100 can be a wafer formed of a semiconductor material such as silicon.

At least a part of the driving circuit DC disposed in each of the sub-pixels RSP, GSP, and BSP, for example, an active layer functioning as a semiconductor of each transistor, can be formed in the substrate 100. Accordingly, in the light emitting display device according to the embodiment of the present disclosure, density of the driving circuits DC formed in respective sub-pixels SP can be enhanced. In addition, in the light emitting display device according to the embodiment of the present disclosure, the process of forming the driving circuits DC of respective sub-pixels RSP, GSP, and BSP can be simplified.

The second transistor TR2 of each of the sub-pixels RSP, GSP, and BSP can generate the drive current according to the data signal. For example, the second transistor TR2 of each of the sub-pixels RSP, GSP, and BSP can function as a driving transistor. The second transistor TR2 of each of the sub-pixels RSP, GSP, and BSP can include a well region 102w, a first source/drain region 102d, a second source/drain region 102s, a gate electrode 223, a first source/drain electrode 225, and a second source/drain electrode 227. For example, in each of the sub-pixels RSP, GSP, and BSP, the gate electrode 223 of the second transistor TR2 can be electrically connected to one of the source/drain electrodes of the first transistor TR1 of FIG. 2, the second source/drain electrode 227 of the second transistor TR2 can be electrically connected to a power voltage supply line PL corresponding to the same sub-pixel, and the first source/drain electrode 225 of the second transistor TR2 can be connected to a corresponding one of the anodes 310 (310R, 310G, and 310B).

The well region 102w and the first and second source/drain regions 102d and 102s can be formed in the substrate 100. For example, the well region 102w and the first and second source/drain regions 102d and 102s can be formed through a process of doping with conductive impurities. The well region 102w and the first and second source/drain regions 102d and 102s can include conductive impurities of different types, respectively. For example, the well region 102w can include an n-type impurity, and the first and second source/drain regions 102d and 102s can include a p-type impurity. The first and second source/drain regions 102d and 102s can be formed in the well region 102w. For example, a portion of the well region 102w disposed between the first and second source/drain regions 102d and 102s can function as a channel region in the second transistor TR2.

Meanwhile, referring to FIG. 4, the first transistor TR1 can be formed in the same process as that of the second transistor TR2. Accordingly, the first transistor TR1 can include a well region disposed in the substrate 100, and source/drain regions disposed in the well region, and the well region of the substrate 100 can be used as an active layer.

Thus, in the light emitting display device according to the embodiment of the present disclosure, a wafer including silicon can be used as the substrate 100, and the well region of the substrate 100 can be used as an active layer of a transistor, and, as such, it can be possible to omit a process of forming a separate active layer. Accordingly, there are advantages in terms of integration and process simplification suitable for realization of fine sub-pixels.

The first and second transistors TR1 and TR2 can be implemented to have different characteristics through doping of the well region and the source/drain regions in the substrate 100 with different impurities. Alternatively, the first and second transistors TR1 and TR2 can be implemented to have different characteristics using different shapes of the well region and the source/drain regions such that widths/lengths of the channel regions of the first and second transistors TR1 and TR2 are different from each other.

The gate electrode 223 can be disposed on the substrate 100. The gate electrode 223 can be disposed between the first source/drain region 102d and the second source/drain region 102s. For example, the gate electrode 223 can overlap with the portion of the well region 102w functioning as a channel region. The gate electrode 223 can include a conductive material. For example, the gate electrode 223 can include a metal such as aluminum (Al), chromium (Cr), copper (Cu), molybdenum (Mo), titanium (Ti), or tungsten (W). The gate electrode 223 can be spaced apart from the substrate 100. The gate electrode 223 can be insulated through inclusion of an insulating layer 110 between the gate electrode 223 and the substrate 100. For example, the portion of the well region 102w functioning as a channel region can have electrical conductivity corresponding to a voltage applied to the gate electrode 223.

The first and second source/drain electrodes 225 and 227 can include a conductive material. For example, the first and second source/drain electrodes 225 and 227 can include a metal such as aluminum (Al), chromium (Cr), copper (Cu), molybdenum (Mo), titanium (Ti), or tungsten (W). The first and second source/drain electrodes 225 and 227 can include a material different from that of the gate electrode 223. The first and second source/drain electrodes 225 and 227 can be disposed on a layer different from that of the gate electrode 223. The first source/drain electrodes 225 can be electrically connected to the first source/drain region 102d, and the second source/drain electrodes 227 can be electrically connected to the second source/drain region 102s. The first source/drain electrode 225 can be insulated from the gate electrode 223.

The storage capacitor Cst of each sub-pixel SP can maintain a voltage applied to the gate electrode 223 of the second transistor TR2 of the same sub-pixel SP for one frame. For example, the storage capacitor Cst of each sub-pixel SP can be electrically connected to the gate electrode 223 and the second source/drain electrode 227 of the second transistor TR2 in the same sub-pixel SP. The storage capacitor Cst of each sub-pixel SP can have a stack structure of capacitor electrodes. For example, the storage capacitor Cst of each sub-pixel SP can include a first capacitor electrode electrically connected to the gate electrode 223 of the same sub-pixel SP, and a second capacitor electrode electrically connected to the second source/drain electrode 227 of the same sub-pixel SP. The storage capacitor Cst of each sub-pixel SP can be formed using a process of forming the first transistor TR1 and the second transistor TR2 in the same sub-pixel SP. For example, the first capacitor electrode of each sub-pixel SP can be disposed on the same layer as that of the gate electrode 223 of the same sub-pixel SP, and the second capacitor electrode of each sub-pixel SP can be disposed on the same layer as that of the second source/drain electrode 227 of the same sub-pixel SP or can be formed to be integrated with the second source/drain electrode 227 of the same sub-pixel SP. Accordingly, in the light emitting display device according to the embodiment of the present disclosure, efficiency of the process of forming the driving circuits DC in respective sub-pixels SP can be enhanced.

A plurality of insulating layers 110, 120, IN, and 140 for preventing unnecessary electrical connection can be disposed on the substrate 100. For example, a gate insulating layer 110, an interlayer insulating layer 120, an insulating layer IN, and fences 140 can be disposed on the substrate 100.

The gate insulating layer 110 can be disposed on the substrate 100. The gate insulating layer 110 can be disposed between the gate electrode 223 and the substrate 100 and, as such, the gate electrode 223 can be insulated from the well region 102w of the substrate 100 by the gate insulating layer 110.

For example, in each of the sub-pixels RSP, GSP, and BSP, an upper surface of the substrate 100 facing the gate electrode 223 of each transistor can be covered by the gate insulating layer 110. The gate insulating layer 110 can directly contact the upper surface of the substrate 100. The gate electrode 223 of each of the sub-pixels RSP, GSP, and BSP can be disposed on the gate insulating layer 110. The gate insulating layer 110 can include an insulating material. For example, the gate insulating layer 110 can include an inorganic insulating material such as silicon oxide (SiOₓ) or silicon nitride (SiNₓ).

The interlayer insulating layer 120 can be disposed on the gate insulating layer 110. The first and second source/drain electrodes 225 and 227 of each of the sub-pixels RSP, GSP, and BSP can be insulated from the gate electrode 223 of the same one of the sub-pixels RSP, GSP, and BSP by the interlayer insulating layer 120. For example, the gate electrode 223 of each of the sub-pixels RSP, GSP, and BSP can be covered by the interlayer insulating layer 120. The first and second source/drain electrodes 225 and 227 of each of the sub-pixels RSP, GSP, and BSP can be disposed on the interlayer insulating layer 120. The interlayer insulating layer 120 can include an insulating material. For example, the interlayer insulating layer 120 can include an inorganic insulating material.

The insulating layer IN can be disposed on the interlayer insulating layer 120. The insulating layer IN can include first to third insulating layers 125, 130, and 132 used as formation surfaces of the first to third reflective electrodes 200R, 200G, and 200B, respectively. The first to third insulating layers 125, 130, and 132 are provided for planarization, and includes an inorganic insulating material or an organic insulating material. As the inorganic insulating material, there can be silicon oxide (SiOₓ), silicon nitride (SiNₓ), or silicon oxynitride (SiNₓO_{y}). The organic insulating material can include one or more of acryl resin, phenolic resin, polyimides resin, unsaturated polyesters resin, polyamides resin, benzocyclobutene, polyphenylene resin, and polyphenylene sulfides resin.

The first to third insulating layers 125, 130, and 132 of the insulating layer IN can remove steps formed by the driving circuits DC of respective sub-pixels RSP, GSP, and BSP.

The first and second source/drain electrodes 225 and 227 of each of the transistors TR1 and TR2 in each of the sub-pixels RSP, GSP, and BSP can be covered by the first insulating layer 125.

An upper surface of each of the first to third insulating layers 125, 130, and 132 is flat and, as such, the first to third reflective electrodes 200R, 200G, and 200B can be disposed on the flat upper surfaces of the first to third insulating layers 125, 130, and 132, respectively.

The first to third insulating layers 125, 130, and 132 can include an organic insulating material or an inorganic insulating material. The first to third insulating layers 125, 130, and 132 can be formed of an organic insulating material or can be formed through stacking of a plurality of inorganic insulating layers in order to achieve easy planarization. A part of the first to third insulating layers 131, 132, and 133 can be constituted by an organic insulating material, and the remaining part of the first to third insulating layers 131, 132, and 133 can be constituted by an inorganic insulating material.

The light emitting element 300 can be provided at each of the sub-pixels RSP, GSP, and BSP and, as such, light of a color having a grayscale corresponding to the same sub-pixel is emitted in accordance with the driving circuit DC of the same sub-pixel. Two facing electrodes of the light emitting element 300, for example, each anode 310 (310R, 310G, or 310B) and the cathode 330, can include conductive materials, respectively.

Transmittance of the anodes 310 (310R, 310B, and 310G) can be greater than that of the cathode 330. For example, each of the anodes 310 (310R, 310B, and 310G) can be a transparent electrode constituted by a transparent conductive material such as indium tin oxide (ITO), indium zinc oxide (IZO), or the like, and the cathode 330 can be a transparent reflective electrode formed of a metal or a metal alloy including at least one of silver (Ag), magnesium (Mg), and ytterbium (Yb) while being formed to have a small thickness. The work function of the cathode 330 can be smaller than that of the anodes 310 (310R, 310B, and 310G).

In the light emitting display device according to the embodiment of the present disclosure, the reflective electrodes 200R, 200G, and 200B are provided under the anodes 310 (310R, 310G, and 310B), respectively, and, as such, light generated from the intermediate layer 320 can be emitted upwards and downwards, and can then repeat resonance according to reflection and re-reflection between the reflective electrodes 200R, 200G, and 200B and the cathode 330. Finally, light exits through the cathode 330.

In the light emitting display device according to the embodiment of the present disclosure, among light of different colors generated by the intermediate layer 320, red light can be amplified by a vertical distance between the first reflective electrode 200R and the first anode 310R disposed at the red sub-pixel RSP. In addition, among light of different colors generated by the intermediate layer 320, green light can be amplified by a vertical distance between the second reflective electrode 200G and the second anode 310G disposed at the green sub-pixel GSP. In addition, among light of different colors generated by the intermediate layer 320, blue light can be amplified by a vertical distance between the third reflective electrode 200B and the third anode 310B disposed at the blue sub-pixel BSP. In the light emitting display device according to the embodiment of the present disclosure, each of the sub-pixels RSP, GSP, and BSP can emit light representing a color different from that of another one of the sub-pixels RSP, GSP, and BSP adjacent thereto using a micro-cavity structure. Accordingly, in the light emitting display device according to the embodiment of the present disclosure, color reproducibility of light emitted from each of the sub-pixels RSP, GSP, and BSP can be enhanced.

The intermediate layer 320 can be formed through stacking of one or more stacks each including a hole injection layer HIL, a hole transport layer HTL, an emission layer EML, an electron transport layer ETL, and an electron injection layer EIL between the anodes 310 and the cathode 330. In this case, the emission layer EML can be an emission layer configured to emit white light.

In the case in which white light is emitted from the intermediate layer 320, color filters 500R, 500B, and 500G can be provided over the light emitting element 300, corresponding to the sub-pixels RSP, BSP, and GSP, respectively, and, as such, colors of the sub-pixels RSP, BSP, and GSP can be represented.

In the light emitting display device according to the embodiment of the present disclosure, it can be possible to disconnect continuity between adjacent ones of sub-pixels RSP, BSP, and GSP by a trench TS provided between the adjacent ones of the sub-pixels RSP, BSP, and GSP, as shown in FIGS. 3 and 4, even when no ultra-fine deposition mask is provided in formation of the intermediate layer 320.

As shown in FIG. 3, the trench TS can be disposed at opposite sides of each anode 310 (310R, 310G, or 310B) of each of the sub-pixels RSP, GSP, and BSP or can have a shape surrounding four sides of each anode 310 (310R, 310G, or 310B) when viewed in a plan view.

The intermediate layer 320 can be disconnected at a portion thereof by the trench TS in an area having a relatively low step. Accordingly, the intermediate layer 320 can be partially separated on a sub-pixel basis and, as such, generation of leakage current between adjacent ones of the sub-pixels can be prevented.

The intermediate layer 320 can generate light with a luminance corresponding to a voltage difference between each anode 310 and the cathode 330.

The fences 140 can be disposed on the second insulating layer 130. The fences 140 can insulate the anode 310 of each of the sub-pixels RSP, GSP, and BSP from the anode 310 of another sub-pixel SP adjacent to the former sub-pixel SP. The fence 140 may overlap with a portion of the anode 310 disposed at a side wall of the trench TS. For example, edges of the anodes 310 disposed in respective sub-pixels RSP, GSP, and BSP can be covered by the fences 140. The fences 140 can include an insulating material. Each fence 140 can be a linear insulating layer having a predetermined thickness. For example, the fences 140 can include an inorganic insulating material.

If necessary, the fences 140 can include a black material in order to obtain an effect of preventing light leakage among the adjacent sub-pixels.

The fences 140 can expose portions of the anodes 310 disposed in respective sub-pixels SP. For example, the fences 140 can define emission areas REA, GEA, and BEA in respective sub-pixels SP. Areas disposed among the emission areas REA, GEA, and BEA can be defined as non-emission areas. For example, an area including the fences 140 and the trench TS can be a non-emission area. Portions of the first and second anodes 310R and 310G in the emission areas REA and GEA of respective sub-pixels RSP, and GSP can directly contact an upper surface of the insulating layer IN. Since the third reflective electrode 200B is disposed on the insulating layer IN, the third anode 310B is disposed to contact an upper surface of the third reflective electrode 200B.

The intermediate layer 320 and the cathode 330 of the sub-pixels RSP, BSP, and GSP can be stacked on the portions of the anodes 310 (310R, 310B, and 310G) exposed by the fences 140. For example, the intermediate layer 320 can directly contact the anodes 310 at a lower surface thereof while directly contacting the cathode 330 at an upper surface thereof. Accordingly, in the light emitting display device according to the embodiment of the present disclosure, luminance deviations according to generation positions of light emitted from the emission areas REA, BEA, and GEA of respective sub-pixels RSP, BSP, and GSP can be prevented.

An encapsulation layer 400 can be disposed on the light emitting element 300 in the sub-pixels RSP, BSP, and GSP. The encapsulation layer 400 can prevent damage of the light emitting element 300 caused by external moisture and impact. The encapsulation layer 400 can have a multilayer structure. For example, the encapsulation layer 400 can include a first encapsulation layer 410, a second encapsulation layer 420, and a third encapsulation layer 430 sequentially stacked in this order. Each of the first encapsulation layer 410, the second encapsulation layer 420, and the third encapsulation layer can include an insulating material. The second encapsulation layer 420 can include a material different from that of the first encapsulation layer 410 and the third encapsulation layer 430. For example, each of the first encapsulation layer 410 and the third encapsulation layer 430 is an inorganic encapsulation layer including an inorganic insulating material, and the second encapsulation layer 420 can be an organic encapsulation layer including an organic insulating material. Accordingly, in the light emitting display device according to the embodiment of the present disclosure, damage of the light emitting element 300 caused by external moisture and impact can be effectively prevented. Steps formed by the light emitting element 300 at the sub-pixels RSP, GSP, and BSP can be removed by the second encapsulation layer 420. For example, an upper surface of the encapsulation layer 400 facing the substrate 100 can be flat. The second encapsulation layer 420 can have a greater thickness than that of each of the first encapsulation layer 410 and the third encapsulation layer 430.

Color filters 500R, 500B, and 500G can be disposed on the encapsulation layer 400. The color filters 500R, 500B, and 500G can overlap with the emission areas REA, BEA, and GEA of the sub-pixels RSP, GSP, and BSP, respectively. The color filters 500R, 500B, and 500G can be disposed to be adjacent to one another and, as such, can overlap with the trench TS.

For example, the color filters 500R, 500B, and 500G can include a red color filter 500R overlapping with the red emission area REA, a blue color filter 500B overlapping with the blue emission area BEA, and a green color filter 500G overlapping with the green emission area GEA.

Each of the color filters 500R, 500B, and 500G can have a greater size than that of a corresponding one of the emission areas REA, BEA, and GEA. For example, a boundary between adjacent ones of the color filters 500R, 500B, and 500G can overlap with the trench TS. Accordingly, in the light emitting display device according to the embodiment of the present disclosure, light emitted from the light emitting element 300 at respective sub-pixels RSP, GSP, and BSP can surely pass through the color filters 500R, 500G, and 500B of respective sub-pixels RSP, GSP, and BSP. Accordingly, in the light emitting display device according to the embodiment of the present disclosure, a light leakage phenomenon can be prevented. In addition, in the light emitting display device according to the embodiment of the present disclosure, color reproducibility can be enhanced.

A protective layer can be disposed on the color filters 500R, 500B, and 500G. The protective layer can prevent damage of the color filters 500R, 500B, and 500G caused by external impact and moisture. The protective layer can include an insulating material. For example, the protective layer can include at least one of an inorganic insulating material and an organic insulating material. The protective layer can have a multilayer structure. For example, the protective layer can have a structure in which an inorganic protective layer constituted by an inorganic insulating material is formed on an organic protective layer constituted by an organic insulating material. Accordingly, in the light emitting display device according to the embodiment of the present disclosure, damage of the color filters 500R, 500B, and 500G caused by external impact and moisture can be prevented.

When resonance effects according to different colors of emitted light are generated in accordance with different vertical phases of the first to third reflective electrodes 200R, 200G, and 200B in the sub-pixels RSP, GSP, and BSP, it can be possible to omit at least one of the color filters 500R, 500G, and 500B in the sub-pixels RSP, GSP, and BSP.

Meanwhile, in the configuration of FIG. 4, a configuration including not only the substrate 100, the gate insulating layer 110, and the interlayer insulating layer 120, but also the gate electrode 223 between the gate insulating layer 110 and the interlayer insulating layer 120, is referred to as an element substrate 1010.

In addition, reference numeral “228” not described with reference to FIG. 5 can designate a connection line or an electrode pattern formed together with the first and second source/drain electrodes 225 and 227.

Hereinafter, various shapes of trenches in light emitting display devices according to embodiments of the present disclosure will be described.

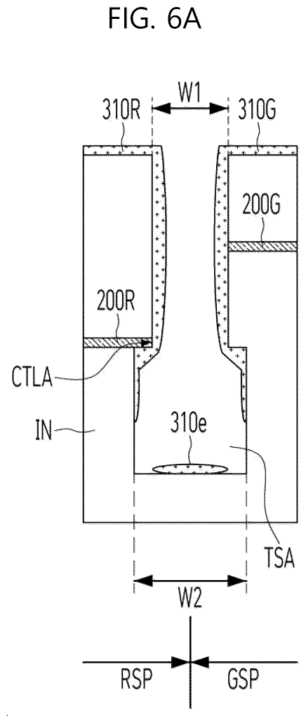

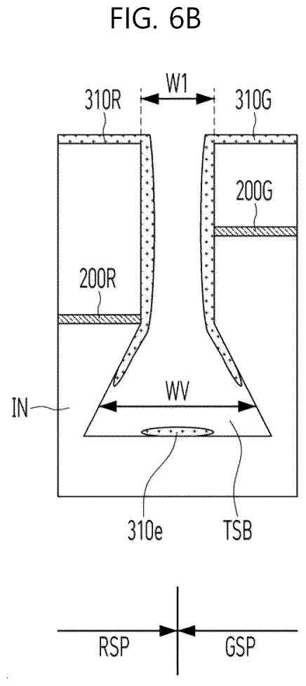

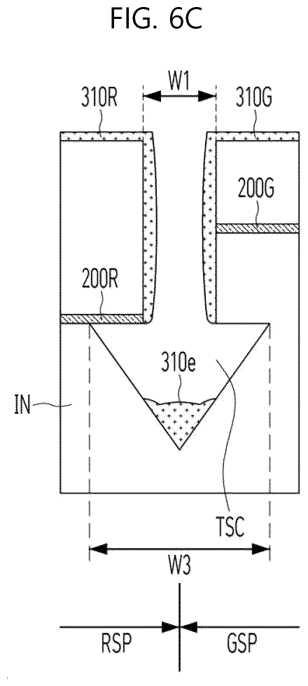

FIGS. 6A to 6C are cross-sectional views showing various examples of trenches according to embodiments of the present disclosure.

As shown in FIG. 6A, when reflective electrodes 200R and 200G are disposed in an insulating layer IN while having different vertical phases in different sub-pixels RSP and GSP adjacent to each other, respectively, a trench TSA can have a side portion having a greater width at a lower part thereof below the first reflective electrode 200R having a deepest vertical phase in the insulating layer IN than at an upper part thereof above the first reflective electrode 200R (W1<W2). In addition, the trench TSA can have a uniform first width W1 at the upper part thereof above the first reflective electrode 200R, and a uniform second width W2 at the lower part thereof below the first reflective electrode 200R.

Accordingly, deposition of an anode material on a side wall of the trench TSA disposed below the first reflective electrode 200R having the deepest vertical phase in the insulating layer IN is ineffectively achieved and, as such, an anode material 310e disposed at a lower surface of the trench TSA is separated from anodes 310R and 310G. The trench TSA is disposed adjacent to sub-pixels configured to emit different colors at opposite sides thereof and, as such, the anodes 310R and 310G at opposite sides of the trench TSA can be separated from each other.

In addition, at opposite sides of the trench TSA, the first anode 310R has a side contact CTLA contacting the first reflective electrode 200R of the red sub-pixel RSP, and the second anode 310G has a side contact CTLB contacting the second reflective electrode 200G of the green sub-pixel GSP and, as such, independent electrical connections between respective reflective electrodes and respective anodes overlapping each other in respective sub-pixels RSP and GSP can be achieved.

As shown in FIG. 6B, when reflective electrodes 200R and 200G are disposed in an insulating layer IN while having different vertical phases in different sub-pixels RSP and GSP adjacent to each other, respectively, a trench TSB can have a side portion having a greater width at a lower part thereof below the first reflective electrode 200R having a deepest vertical phase in the insulating layer IN than at an upper part thereof above the first reflective electrode 200R (W1<WV). In addition, the trench TSB can have a uniform first width W1 at the upper part thereof above the first reflective electrode 200R, and a varying width WV gradually increased at the lower part thereof below the first reflective electrode 200R.

Accordingly, deposition of an anode material on a side wall of the trench TSB disposed below the first reflective electrode 200R having the deepest vertical phase in the insulating layer IN is ineffectively achieved and, as such, an anode material 310e disposed at a lower surface of the trench TSB is separated from anodes 310R and 310G. The trench TSB is disposed adjacent to sub-pixels configured to emit different colors at opposite sides thereof and, as such, the anodes 310R and 310G at opposite sides of the trench TSB can be separated from each other.

In addition, at opposite sides of the trench TSB, the first anode 310R has a side contact CTLA contacting the first reflective electrode 200R of the red sub-pixel RSP, and the second anode 310G has a side contact CTLB contacting the second reflective electrode 200G of the green sub-pixel GSP and, as such, independent electrical connections between respective reflective electrodes and respective anodes overlapping each other in respective sub-pixels RSP and GSP can be achieved.

As shown in FIG. 6C, when reflective electrodes 200R and 200G are disposed in an insulating layer IN while having different vertical phases in different sub-pixels RSP and GSP adjacent to each other, respectively, a trench TSC can have different widths at upper and lower parts thereof with reference to a boundary of the first reflective electrode 200R having a deepest vertical phase in the insulating layer IN such that the trench TSC has an increased width W3 at a lower surface of the first reflective electrode 200R and, as such, separation of an anode material 310e can be achieved at a side wall and a lower surface of the trench TSC. In this case, the trench TSC can have a uniform first width W1 at the upper part thereof above the first reflective electrode 200R, and a second width W3 increased from the first width W1 at the lower surface of the first reflective electrode 200R such that the trench TSC has a width gradually decreased while extending downwards toward a substrate 100. In this case, the trench TSC has a great width difference at the lower surface of the first reflective electrode 200R and, as such, anodes 310R and 310G disposed at side walls of the trench TSC above the first reflective electrode 200R can be separated from the trench TSC at a position below the lower surface of the first reflective electrode 200R. Although the anode material 310e can be deposited at the lower surface of the trench TSC in this case, the anode material 310e can have an island shape and, as such, can be physically spaced apart from the anodes 310R and 310G on the side walls of the trench TSC disposed above the first reflective electrode 200R.

Accordingly, deposition of an anode material on the side walls of the trench TSC disposed below the first reflective electrode 200R having the deepest vertical phase in the insulating layer IN is ineffectively achieved and, as such, the anode material 310e disposed at the lower surface of the trench TSC is separated from anodes 310R and 310G. The trench TSC is disposed adjacent to sub-pixels configured to emit different colors at opposite sides thereof and, as such, the anodes 310R and 310G at opposite sides of the trench TSC can be separated from each other.

In addition, at opposite sides of the trench TSC, the first anode 310R has a side contact CTLA contacting the first reflective electrode 200R of the red sub-pixel RSP, and the second anode 310G has a side contact CTLB contacting the second reflective electrode 200G of the green sub-pixel GSP and, as such, independent electrical connection between respective reflective electrodes and respective anodes overlapping each other in respective sub-pixels RSP and GSP can be achieved.

Hereinafter, a structure of the intermediate layer 320 will be described.

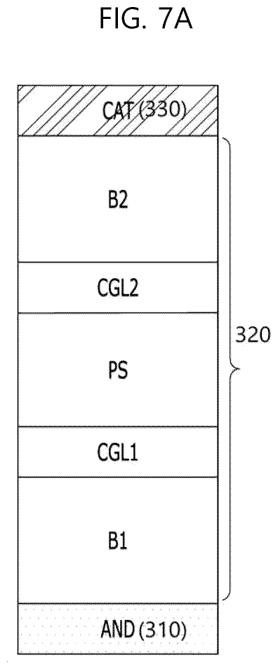

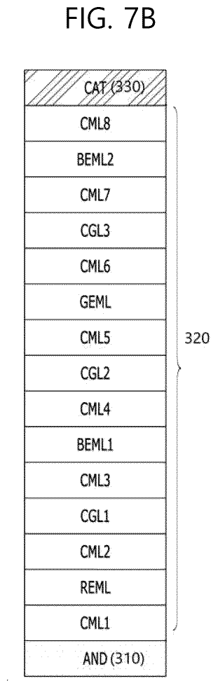

FIGS. 7A and 7B are sectional views showing different forms of the light emitting element according to the embodiment of the present disclosure, respectively.

As another form, the intermediate layer 320 can have a configuration including a plurality of stacks B1, PS, and B2 between an anode AND and a cathode CAT, as shown in FIG. 7A.

Each of the stacks B1, PS, and B2 can include at least one hole transport layer HTL, at least one emission layer EML, and at least one electron transport layer ETL. The stacks B1, PS, and B2 can be divided from one another by charge generation layers CGL1 and CGL2, respectively. Each of the charge generation layers CGL1 and CGL2 can include an n-type charge generation layer configured to generate electrons and to transfer the generated electrons to a lower stack adjacent thereto, and a p-type charge generation layer configured to generate holes and to transfer the generated holes to an upper stack adjacent thereto.

The first reflective electrode 200R having a deepest vertical phase is disposed on the first insulating layer 125 to extend to a side wall of the trench TS. The first reflective electrode 200R is connected to the second transistor TR2 disposed below the first reflective electrode 200R.

The light emitting elements 300 include the reflective electrodes 200R, 200G, and 200B disposed thereunder, respectively, and as such, can block light directly transmitted downwards. In addition, in each embodiment of the present disclosure, each of the reflective electrodes 200R, 200G, and 200B is formed to extend to side walls of the trench TS corresponding thereto and, as such, can block light inclinedly incident thereupon after being emitted from the light emitting element in a sub-pixel adjacent thereto. In this case, leakage light from the adjacent sub-pixel is prevented from being transmitted to a driving circuit disposed under the subject sub-pixel. In addition, since transmission of leakage light to the adjacent sub-pixel is prevented during low-grayscale driving, there is an advantage in that clear display can be achieved.

The intermediate layer 320 can be formed without being divided on a sub-pixel basis, for omission of an ultra-fine mask and convenience of processes. In this case, the trench TS is provided among the sub-pixels RSP, GSP, and BSP in order to prevent generation of lateral leakage current between adjacent ones of the sub-pixels RSP, GSP, and BSP through the intermediate layer 320. Separation of the intermediate layer 320 between adjacent ones of the sub-pixels RSP, GSP, and BSP can be obtained through the trench TS. For example, the intermediate layer 320 disposed at the sub-pixels RSP, GSP, and BSP can be partially separated between adjacent ones of the sub-pixels RSP, GSP, and BSP through the trench TS.

In the case of FIG. 7A, each of the first stack B1 adjacent to the anode AND and the third stack B2 adjacent to the cathode CAT can include a blue emission layer, and the blue emission layer can include at least one of a fluorescent material and a phosphorescent material.

The second stack PS between the first and third stacks B1 and B2 can be configured through inclusion of an emission layer of a longer wavelength than that of blue. The second stack PS can include a plurality of phosphorescent emission layers. If necessary, one of the first stack B1 and the third stack B2 can be omitted and, as such, the intermediate layer 320 can be configured through inclusion of a blue stack BS configured to emit blue, a phosphorescent emission stack PS including a phosphorescent emission layer, and a charge generation layer CGL between the blue stack BS and the phosphorescent emission stack PS.

In this case, light exiting from the light emitting display device 1000 is based on a color of light emitted from the intermediate layer 320. Accordingly, the second stack PS can also include a red emission layer and a green emission layer adjacent to each other in order to enable expression of pure colors of light from individual light emitting elements.

The cathode 330 can be formed in a deposition process, and can be provided in the active area AA while having a smaller thickness than that of the intermediate layer 320.

FIG. 7B shows another form of the intermediate layer 320 of the light emitting element 300 including a plurality of stacks. The intermediate layer 320 of FIG. 7B is different from that of FIG. 7A in terms of disposition of emission layers while including an increased number of stacks. In the light emitting element according to FIG. 7B, the intermediate layer 320 disposed between the anode AND and the cathode CAT is configured through inclusion of a first common layer CML1, a red emission layer REML, a second common layer CML2, a first charge generation layer CGL1, a third common layer CML3, a first blue emission layer BEML1, a fourth common layer CML4, a second charge generation layer CGL2, a fifth common layer CML5, a green emission layer GEML, a sixth common layer CML6, a third charge generation layer CGL3, a seventh common layer CML7, a second blue emission layer BEML2, and an eighth common layer CML8.

Each of stacks divided from one another by the charge generation layers CGL1, CGL2, and CGL3 includes a single emission layer. The single emission layer can be disposed at an optimum distance corresponding to a color to be emitted and, as such, emission expression of pure colors to be displayed by respective sub-pixels RSP, GSP, and BSP can be more reliably possible.

In the intermediate layer 320, each of the first common layer CML1, the third common layer CML3, the fifth common layer CML5, and the seventh common layer CML7 can include a hole transport layer, and each of the second common layer CML2, the fourth common layer CML4, the sixth common layer CML6, and the eighth common layer CML8 can include an electron transport layer.

The first common layer CML1 adjacent to the anode AND can further include a hole injection layer, and the eighth common layer CML8 adjacent to the cathode CAT can further include an electron injection layer.

The plurality of sub-pixels RSP, BSP, and GSP provided at the substrate 100 can include a red sub-pixel RSP, a blue sub-pixel BSP, and a green sub-pixel GSP.

Meanwhile, in the light emitting display device according to each embodiment of the present disclosure, the intermediate layer 320 can be formed in the entirety of the active area AA in a deposition process. In this case, it is unnecessary to provide a deposition mask requiring openings for respective sub-pixels of high resolution in a process of forming the intermediate layer 320 and the cathode 330. Accordingly, there is an advantage in that production yield is increased in accordance with omission of a fine deposition mask.

### Second Embodiment

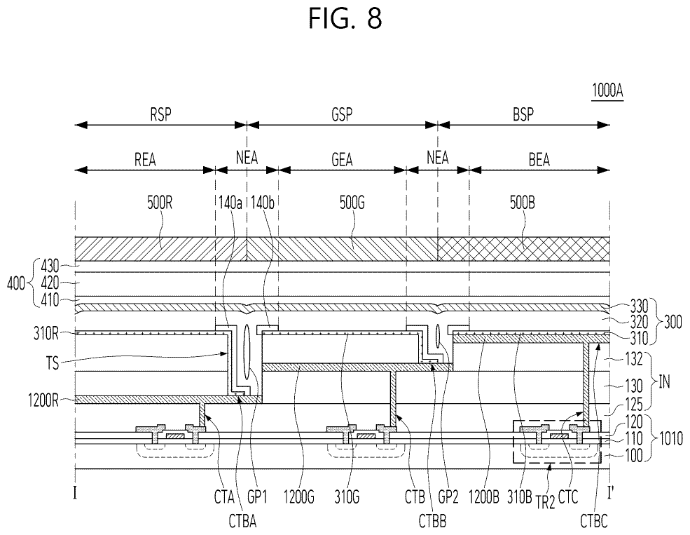

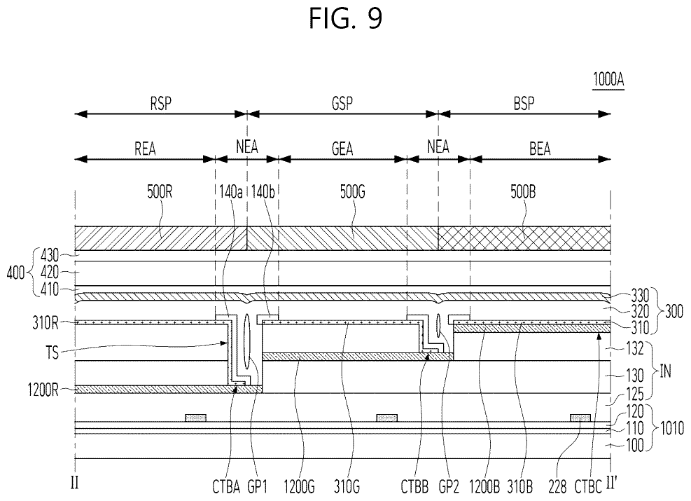

FIG. 8 is a cross-sectional view taken along line I-I′ in FIG. 3 in accordance with a second embodiment of the present disclosure. FIG. 9 is a cross-sectional view taken along line II-II′ in FIG. 3 in accordance with the second embodiment of the present disclosure.

As shown in FIGS. 8 and 9, in a light emitting element according to the second embodiment of the present disclosure, lower surfaces of trenches TS disposed among sub-pixels RSP, GSP, and BSP can be disposed at upper surfaces of reflective electrodes 1200R, 1200G, and 1200B adjacent to the trenches TS, respectively.

In this case, at the lower surfaces of the trenches TS in respective sub-pixels RSP, GSP, and BSP, anodes 310R, 310G, and 310B can be connected to the upper surfaces of the reflective electrodes 1200R, 1200G, and 1200B disposed thereunder by contacts CTBA, CTBB, CTBC, respectively. Respective anode may contact an upper surface of respective reflective electrode at a portion of a lower surface of the trench TS.

In this case, the reflective electrodes 1200R, 1200G, and 1200B extend not only along emission areas REA, GEA, BEA, respectively, but also extend to the trenches TS adjacent thereto, respectively. Accordingly, each of the reflective electrodes 1200R, 1200G, and 1200B may not only directly reflect light generated from a light emitting element 300 of a corresponding one of the sub-pixels RSP, GSP, and BSP, but also can prevent light leaking laterally from the adjacent sub-pixel from being transmitted to transistors TR1 and TR2 disposed thereunder. As a result, it can be possible to solve a problem of generation of photoelectric current of the transistors TR1 and TR2 caused by internal light of the light emitting display device.

In this case, anodes 310 (310R, 310G, and 310B) can extend from the emission areas REA, GEA, and BEA of the sub-pixels RSP, GSP, and BSP to side walls of the trenches TS and portions of the lower surfaces of the trenches TS, respectively.

Since the anodes 310 (310R, 310G, and 310B) should be spaced apart from one another between adjacent ones of the sub-pixels RSP, GSP, and BSP, the anodes 310 (310R, 310G, and 310B) can be patterned using a mask. In this case, one edge of each of the anodes 310 (310R, 310G, and 310B) can be disposed at the lower surface of the corresponding trench TS, and the other edge of each of the anodes 310 (310R, 310G, and 310B) can be disposed on the insulating layer IN without overlapping with the corresponding trench TS.

In addition, a first fence 140a can be provided to surround the one edge of each anode 310 disposed at the lower surface of the corresponding trench TS in order to effectively achieve separation of adjacent ones of the anodes 310R, 310G, and 310B.

The other edge of each of the anodes 310 (310R, 310G, and 310B) disposed on the insulating layer IN can be protected by a second fence 140b.

In FIGS. 8 and 9, first and second air gaps GP1 and GP2 in respective trenches TS are shown. In the light emitting display device according to the second embodiment of the present disclosure, the trenches TS have different depths in accordance with vertical phases of the reflective electrodes 1200R, 1200G, and 1200B adjacent thereto and, as such, the second air gap GP2 formed in the trench TS having a relatively small depth can be small.

The trenches TS are provided in order to separate at least a part of a plurality of layers constituting an intermediate layer 320. At least a part of the plurality of layers constituting the intermediate layer 320 is separated between adjacent ones of the sub-pixels RSP, GSP, and BSP at opposite sides of the first air gap GP1 or the second air gap GP2 and, as such, a horizontal continuous structure of the intermediate layer 320 is disconnected among the sub-pixels and, as such, independent driving on a sub-pixel basis is possible, and generation of lateral leakage current can be prevented.

In addition, the reflective electrodes 1200R, 1200G, and 1200B are connected to second transistors TR2, respectively, and, as such, a triple current path between respective driving circuits DC and respective reflective electrodes 1200R, 1200G, and 1200B can be established.

### Third Embodiment

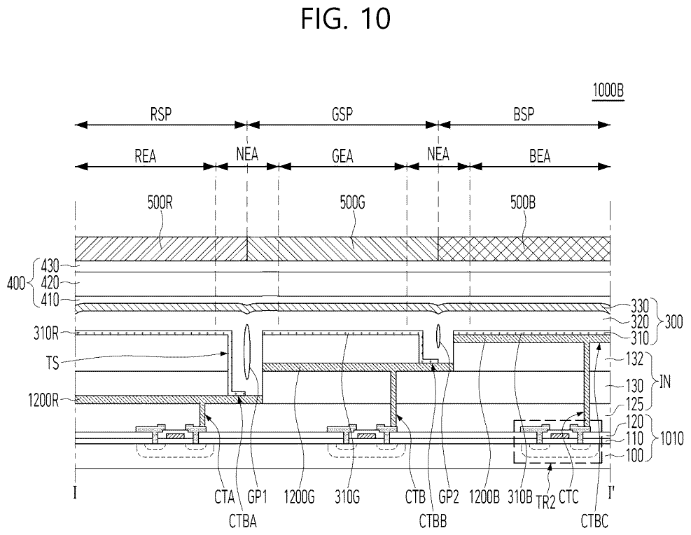

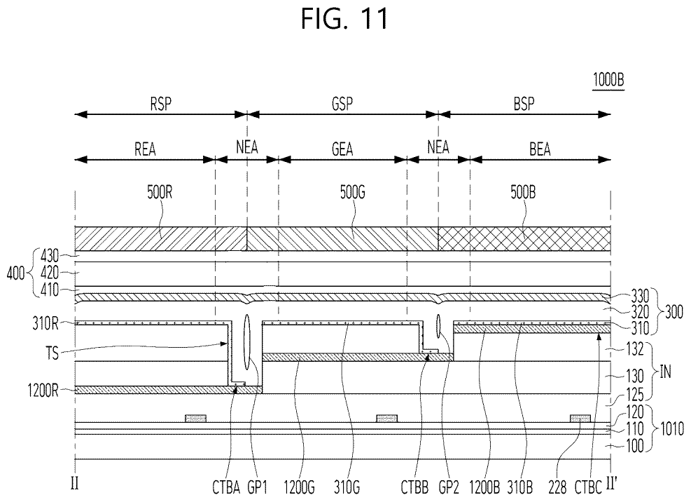

FIG. 10 is a cross-sectional view taken along line I-I′ in FIG. 3 in accordance with a third embodiment of the present disclosure. FIG. 11 is a cross-sectional view taken along line II-II′ in FIG. 3 in accordance with the third embodiment of the present disclosure.

As shown in FIGS. 10 and 11, the light emitting display device according to the third embodiment of the present disclosure is different from that of the second embodiment in that the fences 140a and 140b are omitted.

In this case, portions of anodes 310R, 310G, and 310B disposed at side walls of trenches TS can contact an intermediate layer 320.

When lower surfaces of the trenches TS are observed through FIGS. 10 and 11, a first reflective electrode 1200R and the first anode 310R overlapping each other in a red emission area REA extend to a corresponding one of the trenches TS and, as such, are connected to each other, a second reflective electrode 1200G and the second anode 310G overlapping each other in a green emission area GEA extend to a corresponding one of the trenches TS and, as such, are connected to each other, and a third reflective electrode 1200B and the third anode 310B overlapping each other in a blue emission area BEA extend to a corresponding one of the trenches TS and, as such, are connected to each other.

For example, in the light emitting display device according to the third embodiment of the present disclosure, each reflective electrode and each anode corresponding to each other are connected to each other in an area other than an emission area and, as such, an upper surface of an insulating layer IN neighboring the trench TS can be used as an emission area on the whole. In this case, there is an advantage in that the emission area is extended.

The reflective electrodes 1200R, 1200G, and 1200B of respective sub-pixels are connected to the anodes 310R, 310G, and 310B at lower surfaces of corresponding ones of the trenches TS while having surface contacts CTBA, CTBB, and CTBC, respectively, and, as such, a triple current path between respective driving circuits DC and respective reflective electrodes 1200R, 1200G, and 1200B can be established.

In the light emitting display device according to each embodiment of the present disclosure, portions of the intermediate layer are separated from each other between adjacent ones of the sub-pixels through a trench structure between the adjacent sub-pixels and, as such, it can be possible to prevent generation of lateral leakage current caused by a horizontal continuous structure of a layer having high electrical conductivity in the intermediate layer.

In the light emitting display device according to each embodiment of the present disclosure, each reflective electrode is connected to an anode corresponding thereto at a side wall of a trench and, as such, connection between the reflective electrode and the anode or connection between the anode and a transistor corresponding thereto can be omitted. Accordingly, an ineffective area allocated to the anode for connection of the anode to a driving circuit including the transistor can be reduced and, as such, an enhancement in aperture ratio can be achieved. Thus, higher resolution can be achieved.

The light emitting display device according to each embodiment of the present disclosure can prevent influence between adjacent sub-pixels caused by light emitted from the sub-pixels and, as such, stable low-grayscale expression can be achieved.

In the light emitting display device according to each embodiment of the present disclosure, a process of interconnecting an anode and a transistor can be omitted and, as such, there is an advantage of process optimization. In addition, there is an advantage in that greenhouse gas emissions can be reduced in accordance with reduced processes.

In the light emitting display device according to each embodiment of the present disclosure, an effective emission area of an anode is increased and, as such, the light emitting display device can have effects of reduced power consumption, high efficiency, and high luminance, thereby having sustainability. Thus, environmental/social/governance (ESG) goals can be achieved.

A light emitting display device according to one embodiment of the present disclosure can comprise a substrate comprising a driving circuit at each of sub-pixels, an insulating layer on the driving circuit, a reflective electrode disposed in the insulating layer and connected to the driving circuit, a trench provided in the insulating layer while neighboring the reflective electrode and a light emitting element comprising an anode overlapping with the reflective electrode and contacting the reflective electrode at an interior of the trench.

In a light emitting display device according to one embodiment of the present disclosure, the anode can contact the reflective electrode at a side wall of the trench.

In a light emitting display device according to one embodiment of the present disclosure, the trench can have a lower surface disposed at a deeper level than the reflective electrode.

In a light emitting display device according to one embodiment of the present disclosure, the reflective electrode can have a contact contacting the driving circuit in an emission area of the sub-pixel corresponding thereto.

In a light emitting display device according to one embodiment of the present disclosure, the reflective electrode can contact the side wall of the trench.

In a light emitting display device according to one embodiment of the present disclosure, the trench can have a greater width at a lower part thereof than at an upper part thereof.

In a light emitting display device according to one embodiment of the present disclosure, the reflective electrode can be disposed in the insulating layer while having a vertical phase different from a vertical phase of another reflective electrode in an adjacent one of the sub-pixels and the trench can have a lower surface disposed below one of the reflective electrodes having a deepest vertical phase in the insulating layer.

In a light emitting display device according to one embodiment of the present disclosure, the reflective electrode can be disposed in the insulating layer while having a vertical phase different from a vertical phase of another reflective electrode in an adjacent one of the sub-pixels and the trench can have a lower surface disposed below one of the reflective electrodes having a deepest vertical phase in the insulating layer, and may have a greater width at a lower part thereof than at an upper part thereof.

In a light emitting display device according to one embodiment of the present disclosure, the anode can be separated at the side wall of the trench from an anode material at a lower surface of the trench.

In a light emitting display device according to one embodiment of the present disclosure, the anode can contact an upper surface of the reflective electrode at a portion of a lower surface of the trench.

In a light emitting display device according to one embodiment of the present disclosure, the anode can extend to the side wall of the trench and the lower surface of the trench from an emission area of the sub-pixel corresponding thereto.

In a light emitting display device according to one embodiment of the present disclosure, the light emitting element can comprise an intermediate layer and a cathode on the anode, the intermediate layer can comprise a plurality of stacks divided from one another by a charge generation layer and each of the stacks can comprise a hole transport layer, an emission layer, and an electron transport layer.

A light emitting display device according to one embodiment of the present disclosure can further comprise a fence overlapping with a portion of the anode disposed at a side wall of the trench.

A light emitting display device according to one embodiment of the present disclosure can further comprise an encapsulation layer and a color filter disposed on the light emitting element.

In a light emitting display device according to one embodiment of the present disclosure, a portion of the anode disposed at a side wall of the trench can contact the intermediate layer.

In a light emitting display device according to one embodiment of the present disclosure, the driving circuit can comprise at least one transistor. The at least one transistor can comprise a first source-drain region and a second source-drain region provided in the substrate comprising silicon, a gate electrode disposed on the substrate between the first source-drain region and the second source-drain region and a first source-drain electrode and a second source-drain electrode respectively disposed at opposite sides of the gate electrode while being connected to the first and second source-drain regions.

Although the various embodiments of the present disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A light emitting display device comprising:
a substrate comprising a driving circuit for at least one of sub-pixels;
an insulating layer on the driving circuit;
a reflective electrode disposed in the insulating layer and connected to the driving circuit;
a trench provided in the insulating layer while neighboring the reflective electrode; and
a light emitting element comprising an anode overlapping with the reflective electrode, the anode contacting the reflective electrode at an interior of the trench.

2. The light emitting display device according to claim 1, wherein the anode contacts the reflective electrode at a side wall of the trench.

3. The light emitting display device according to claim 2, wherein the trench has a lower surface disposed at a deeper level than the reflective electrode.

4. The light emitting display device according to claim 2, wherein the reflective electrode has a contact contacting the driving circuit in an emission area of the sub-pixel corresponding thereto.

5. The light emitting display device according to claim 2, wherein the reflective electrode contacts the side wall of the trench.

6. The light emitting display device according to claim 1, wherein the trench has a greater width at a lower part of the trench than at an upper part of the trench.

7. The light emitting display device according to claim 1, wherein:
the reflective electrode is disposed in the insulating layer while having a vertical phase different from a vertical phase of another reflective electrode in an adjacent one of the sub-pixels; and
the trench has a lower surface disposed below one of the reflective electrodes having a deepest vertical phase in the insulating layer.

8. The light emitting display device according to claim 1, wherein:
the reflective electrode is disposed in the insulating layer while having a vertical phase different from a vertical phase of another reflective electrode in an adjacent one of the sub-pixels; and
the trench has a lower surface disposed below one of the reflective electrodes having a deepest vertical phase in the insulating layer, and has a greater width at a lower part thereof than at an upper part thereof.

9. The light emitting display device according to claim 2, wherein the anode is separated at the side wall of the trench from an anode material at a lower surface of the trench.

10. The light emitting display device according to claim 1, wherein the anode contacts an upper surface of the reflective electrode at a portion of a lower surface of the trench.

11. The light emitting display device according to claim 10, wherein the anode extends to the side wall of the trench and the lower surface of the trench from an emission area of the sub-pixel corresponding thereto.

12. The light emitting display device according to claim 1, wherein:
the light emitting element comprises an intermediate layer and a cathode on the anode;
the intermediate layer comprises stacks divided from one another by a charge generation layer; and
each of the stacks comprises a hole transport layer, an emission layer, and an electron transport layer.

13. The light emitting display device according to claim 1, further comprising:
a fence overlapping with a portion of the anode disposed at a side wall of the trench.

14. The light emitting display device according to claim 1, further comprising:
an encapsulation layer and a color filter disposed on the light emitting element.

15. The light emitting display device according to claim 12, wherein a portion of the anode disposed at a side wall of the trench contacts the intermediate layer.

16. The light emitting display device according to claim 1, wherein:
the driving circuit comprises at least one transistor; and
the at least one transistor comprises:
a first source-drain region and a second source-drain region provided in the substrate comprising silicon;
a gate electrode disposed on the substrate between the first source-drain region and the second source-drain region; and
a first source-drain electrode and a second source-drain electrode respectively disposed at opposite sides of the gate electrode while being connected to the first and second source-drain regions.
